(19) United States
(12) Patent Application Publication
(10) Pub. No.: US 2012/0075822 A1
(43) Pub. Date: Mar. 29, 2012

(54) ORGANIC PRINTED CIRCUIT BOARD HAVING REINFORCED EDGE FOR USE WITH WIRE BONDING TECHNOLOGY

(75) Inventors: Hamid Habibi, Calabasas, CA (US); Jin Zhang, Porter Ranch, CA (US); Reza Imani, Moorpark, CA (US); Asghar Dadashian, Northridge, CA (US)

(73) Assignee: PACESETTER, INC., Sylmar, CA (US)

(21) Appl. No.: 12/893,634

(22) Filed: Sep. 29, 2010

(51) Int. Cl. H05K 7/00; B32B 37/02

(52) U.S. Cl. 361/783; 156/60

(57) ABSTRACT

Disclosed herein are electronic devices, such as, for example, televisions, stereo systems, diagnostic equipment, cell phones, desktop or laptop PCs, medical pulse generators, or etc., including an integrated circuit including a printed circuit board including multiple layers and a wire bond pad. The multiple layers are sandwiched together in a planar unitary structure including a top surface, a bottom surface and a structure edge extending between the top surface and the bottom surface. The multiple layers include a first organic substrate layer joined to a second organic substrate layer. Each organic substrate layer includes a layer edge and a peripheral surface adjacent the layer edge. Each layer edge forms part of the structure edge. The wire bond pad includes an outer face, an inner face generally opposite the outer face, and a first rib. The inner face extends along the structure edge. The first rib projects generally perpendicular from the inner face between the first organic substrate layer and the second organic substrate layer and extends along the peripheral surface of at least one of the first organic substrate layer or the second organic substrate layer.

### FIELD OF THE INVENTION

The present invention relates to electronic devices and methods of manufacturing electronic devices. More specifically, the present invention relates to printed circuit boards and methods of manufacturing and electrically connecting printed circuit boards.

### BACKGROUND OF THE INVENTION

Electronic devices employ integrated circuits (“IC”). Wire bond technology, automatic testing (“ATE”) and automatic pick-and-place machines and/or soldering machines, if capable of being used in conjunction, can offer reduced size, reduced manufacturing costs and improved robustness for IC employed in electronic devices. The ability to provide IC of reduced size, reduced manufacturing costs and improved robustness is of increased importance for compact electronic devices such as, for example, cell phones, laptop personal computers, and medical pulse generators (e.g., pacemakers, implantable cardioverter defibrillators (“ICD”), neurostimulators, etc.).

Wire bond technology is widely used in silicon and ceramic substrate based circuit board and IC packaging processes. During wire bonding, force and ultrasonic are applied within a certain time to wire and the pads. Consequently, both the pad and substrate materials need to be solid enough not to dampen the applied energy and force. Since ceramic and silicon substrates are made of hard materials and can withstand the applied force and ultrasonic, the wire bond pad can be located on the top, bottom or side of the board as dictated by the design configurations of the IC and electronic device in which the IC is to be located.

ATE and automatic pick-and-place machines and/or soldering machines require large panelized boards to achieve the manufacturing efficiency necessary to achieve a substantial decrease in manufacturing costs for the IC. Unfortunately, in current manufacturing processes, silicon and ceramic boards cannot be set into the required panelized form.

An organic printed circuit board (“PCB”), such as, for example, a N.E.M.A. FR-4, can be panelized and has a much lower cost than its silicon or ceramic counter part. Unfortunately, it is more difficult to implement side pads for wire bond purposes in an organic PCB. Specifically, wire bond technology in an organic PCB will only allow the bonding pad to be located on the top or bottom layer of the organic PCB. A wire bond pad located on the side edge of an organic PCB will potentially have reliability issues due to the flexible nature of organic material. The force and ultrasonic applied to a flexible (soft) board can cause either a dent in the side pad, a weak bond strength between the wire bond and the pad, or a crack on the wire heel.

There is a need in the art for systems, devices and methods for addressing the above-mentioned shortcomings.

### BRIEF SUMMARY OF THE INVENTION

Disclosed herein is an electronic device, such as, for example, a cell phone, laptop PC, medical pulse generator, or etc. In one embodiment, the electronic device includes an integrated circuit including a printed circuit board including multiple layers and a wire bond pad. The multiple layers are sandwiched together in a planar unitary structure including a top surface, a bottom surface and a structure edge extending between the top surface and the bottom surface. The multiple layers include a first organic substrate layer joined to a second organic substrate layer. Each organic substrate layer includes a layer edge and a peripheral surface adjacent the layer edge. Each layer edge forms part of the structure edge. The wire bond pad includes an outer face, an inner face generally opposite the outer face, and a first rib. The inner face extends along the structure edge. The first rib projects generally perpendicular from the inner face between the first organic substrate layer and the second organic substrate layer and extends along the peripheral surface of at least one of the first organic substrate layer or the second organic substrate layer.

Disclosed herein is a method of manufacturing an electronic device, such as, for example, a cell phone, laptop PC, medical pulse generator, or etc. In one embodiment, the method includes providing a device housing; assembling a printed circuit board for an integrated circuit; and placing the printed circuit board in the device housing. The printed circuit board is assembled by the method of: a) providing a first organic substrate layer comprising a layer edge and a peripheral surface adjacent the layer edge; b) providing a second organic substrate layer comprising a layer edge and a peripheral surface adjacent the layer edge; c) providing a rib that extends along the peripheral surface of at least one of the first organic substrate layer or the second organic substrate layer; d) joining together into a sandwiched planar unitary structure the first organic substrate layer with the second organic substrate layer, the resulting sandwiched planar unitary structure comprising a top surface, a bottom surface and a structure edge extending between the top surface and the bottom surface, each layer edge forming part of the structure edge; e) providing a wire bond pad comprising an outer face and an inner face generally opposite the outer face; f) applying the wire bond pad to the sandwiched planar unitary structure such that the inner face extends along the structure edge; and g) joining the first rib to the inner face such that the first rib projects generally perpendicular from the inner face, the first rib extending between the first organic substrate layer and the second organic substrate layer.

While multiple embodiments are disclosed, still other embodiments of the present invention will become apparent to those skilled in the art from the following detailed description, which shows and describes illustrative embodiments of the invention. As will be realized, the invention is capable of modifications in various aspects, all without departing from the spirit and scope of the present invention. Accordingly, the drawings and detailed description are to be regarded as illustrative in nature and not restrictive.

### BRIEF DESCRIPTION OF THE DRAWINGS

FIG. 1 is an anterior view of a heart shown in partial cross section with a pulse generator system coupled to the heart.

FIG. 2 is a side view of the pulse generator, wherein the wall of the can is removed to shown the contents of the pulse generator housed within the can.

FIG. 3 is an isometric cross sectional view of the organic PCB.

FIG. 4 is an isometric view of the organic PCB.

FIG. 5 is a cross sectional isometric view as taken along section line 5-5 in FIG. 4.

FIG. 6 is an enlarged side view of a portion of the cross section side of the side wire bond pad of FIG. 5.

### DETAILED DESCRIPTION

Disclosed herein are electronic devices, such as, for example, televisions, stereo systems, diagnostic equipment, cell phones, desktop or laptop PCs, medical pulse generators, or etc. employing IC including an organic PCB with side pads capable of withstanding the forces applied in wire bond technology employed in automatic pick-and-place machines and/or soldering machines. Since the organic PCB can be provided in a panelized form and has the edge strength to withstand the forces applied in wire bond technology, the organic PCB is capable of taking advantage of all the benefits of wire bond technology, ATE and automatic pick-and-place machines and/or soldering machines. Consequently, the resulting IC has reduced size, reduced manufacturing costs and improved robustness as compared to IC not capable of taking advantage of all the aforementioned processes.

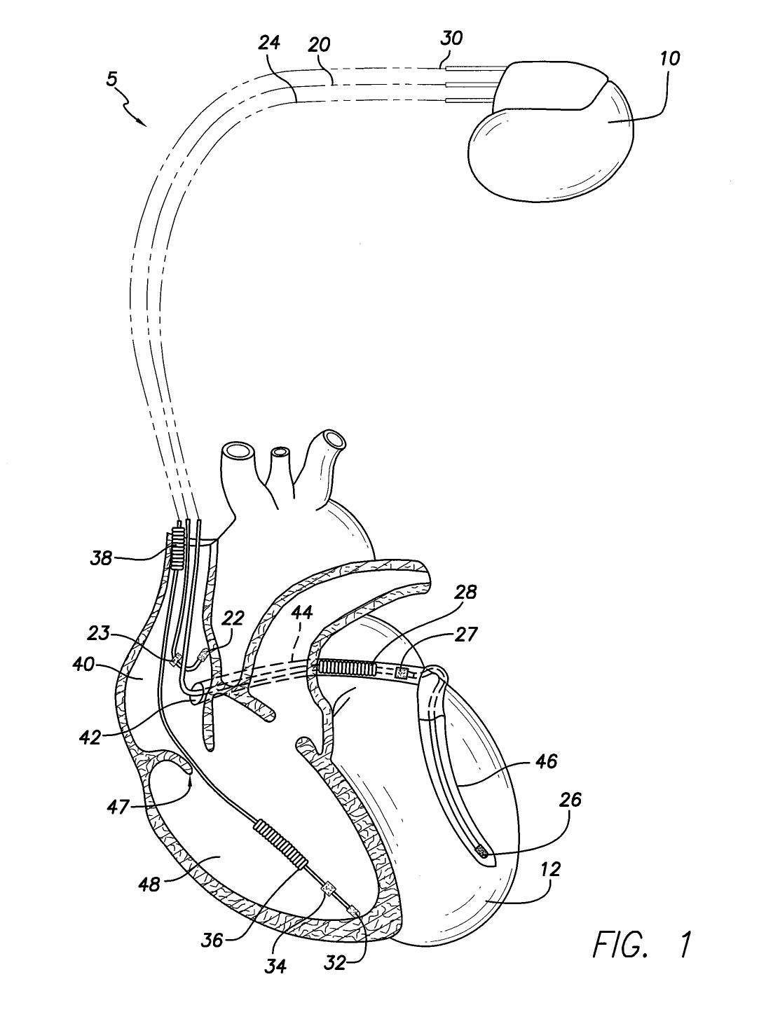

For a discussion of one embodiment of an electronic device employing the IC with the organic PCB disclosed herein, reference is made to FIG. 1, which is an anterior view of a heart 12 shown in partial cross section with a pulse generator system 5 coupled to the heart. As shown in FIG. 1, the system includes an implantable pulse generator 10 such as, for example, a pacemaker or ICD and one or more implantable leads 20, 24, 30. A distal region of a lead may include one or more of the following items: a tip electrode 22, 26, 32, a ring electrode 23, 27, 34 proximal the tip electrode, and a defibrillation or shock coil 28, 36, 38 proximal the ring electrode.

A lead may be configured for passive fixation in the heart 12. In one embodiment, a distal region of a lead may be configured for passive fixation such as, for example, the lead body being configured to bias against the walls of the coronary sinus to passively maintain the lead in place. In one embodiment, the distal tip of a lead may be configured for passive fixation such as, for example, the lead distal tip having pliable tines radiating from the lead distal tip. In embodiments where the lead is configured for passive fixation, the tip electrode 22, 26, 32 may be in the form of a ring or semi-spherical dome.

The lead may be configured for active fixation. In one embodiment, a distal tip of a lead may be configured for active fixation, wherein the tip electrode 22, 26, 32 is in the form of a helical anchor electrode that allows the electrode to be screwed into cardiac tissue.

A proximal end of each lead 20, 24, 30 is coupled to the pulse generator 10 and the leads extend distally into the heart 12. For example, one lead 20 may extend from the pulse generator into the right atrium 40 where the lead tip electrode 22 is passively or actively fixed to a wall of the right atrium. Another lead 24 may extend from the pulse generator, through the right atrium, the coronary sinus ostium (OS) 42, and the coronary sinus 44, and into the left coronary vein 46. Yet another lead 30 may extend form the pulse generator, through the right atrium and tricuspid annulus 47 and into the right ventricle 48, the tip electrode 32 passively or actively fixed to the wall of the right ventricle near the right ventricular apex 50. As understood by those of ordinary skill in the art, the pulse generator, via the leads, provides electrotherapy to the heart tissue and senses heart electrical activity.

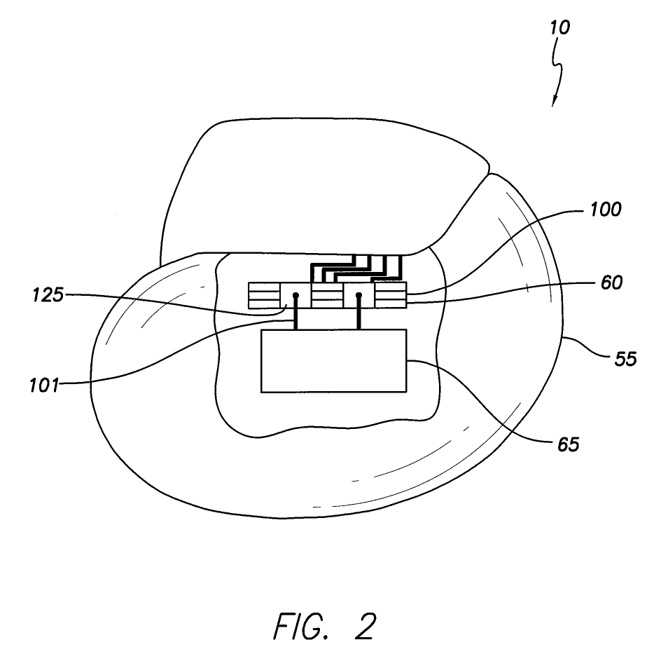

For a discussion of the contents of an example electronic device, which in this example, is the above-mentioned pulse generator 10 of FIG. 1, reference is made to FIG. 2, which is a side view of the pulse generator, wherein the wall of the can 55 is partially removed to shown the contents of the pulse generator 10 housed within the can 55. As shown in FIG. 2, an IC 60 is located within the can 55. The IC 60, along with other similar electronic elements 65 of the pulse generator 10, forms the electronic components of the pulse generator 10 that makes it possible for the pulse generator 10 to provide electrotherapy and sense electrical activity via the leads. The IC 60 may include an organic PCB 100 that is electrically coupled to other the other electronic elements 65 via wire bonds 101 attached to bond pads 125 via a wire bonding process.

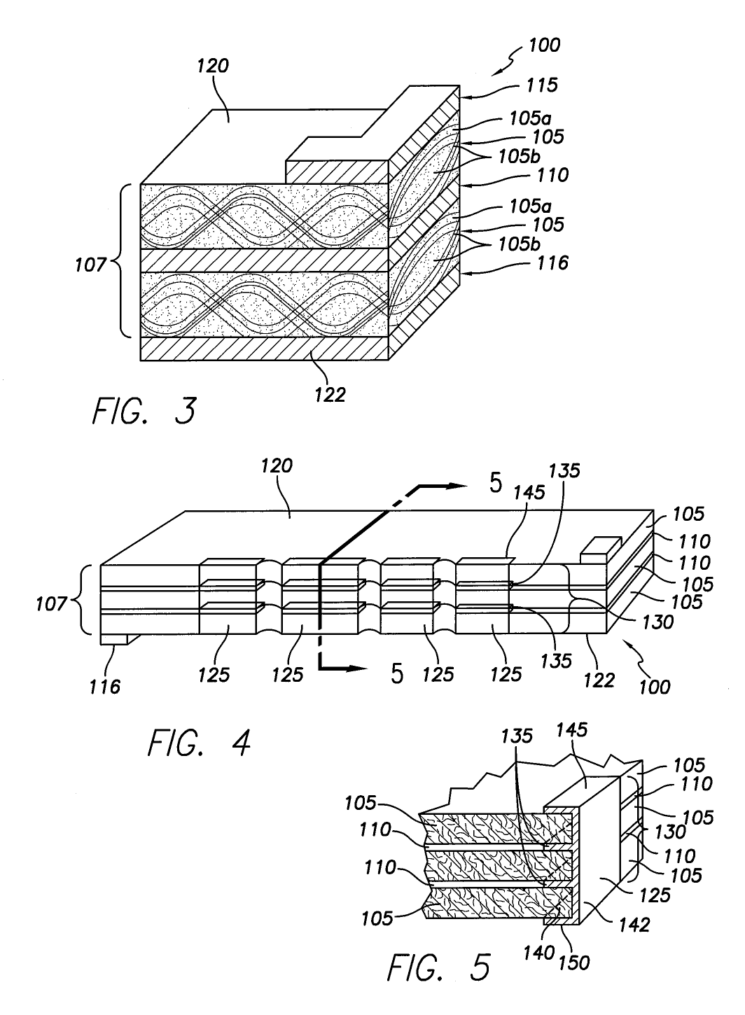

To begin a discussion of the configuration of the organic PCB disclosed herein and which may be employed in the IC of the pulse generator or any other electronic device (e.g., television, stereo system, diagnostic equipment, cell phone, desktop or laptop PCs, or etc.), reference is made to FIG. 3, which is an isometric cross sectional view of the organic PCB 100. As shown in FIG. 3, the PCB 100 includes multiple planar layers 105, 110 that are sandwiched together in such a manner so as to form a laminated organic PCB substrate 107 that has a unitary construction. Some of the planar layers of the unitary substrate are organic substrate layers 105 formed of a binder material 105a in which a fiber or carrier material 105b is embedded. An example organic substrate layer 105 is FR-4, which is the N.E.M.A. grade designation for glass reinforced epoxy laminate sheets and PCB made of woven fiberglass cloth with an epoxy resin binder that is flame resistant (self-extinguishing). The other planar layers of the unitary substrate are joining layers 110. Each joining layer 110 is sandwiched between adjacent organic substrate layers 105 to join the adjacent organic substrate layers together, as shown in FIG. 3.

In one embodiment, the binder material 105a is an epoxy resin or high temperature epoxy resin, the carrier material 105b is fiberglass, and the joining layer 110 is formed of epoxy or high temperature epoxy resin. Where the joining layer is an epoxy, the epoxy may be by Dow Chemical, Nan Ya Plastics, or Kingboard Specialty Resins Limited.

As can be understood from FIG. 3, a top trace layer or wire bond pad 115 and a bottom trace layer or wire bond pad 116 may be respectively supported on the top surface 120 and the bottom surface 122 of the organic PCB substrate 107. The wire bond pads 115, 116 may cover a relatively small area of an outer surface of the organic PCB substrate 107, as indicated by the top wire bond pad 115 in FIG. 3, or a relatively large area of an outer surface of the organic PCB substrate, as illustrated by bottom wire bond pad 116 in FIG. 3. The wire bond pads 115, 116 may be formed on the respective surfaces 120, 122 via such methods as etching or sputtering, and the wire bond pads 115, 116 may be formed of such electrically conductive materials as stainless steel, nickel, copper, gold, platinum or silver.

As indicated in FIG. 4, which is an isometric view of the organic PCB 100, the organic PCB may have side or edge wire bond pads 125 on the side or edge 130 of the organic PCB substrate 107. Specifically, the sides or edges 130 of the organic PCB substrate 107 can be considered to be those surfaces extending vertically between the top surface 120 and the bottom surface 122 when the surfaces 120, 122 are generally horizontal.

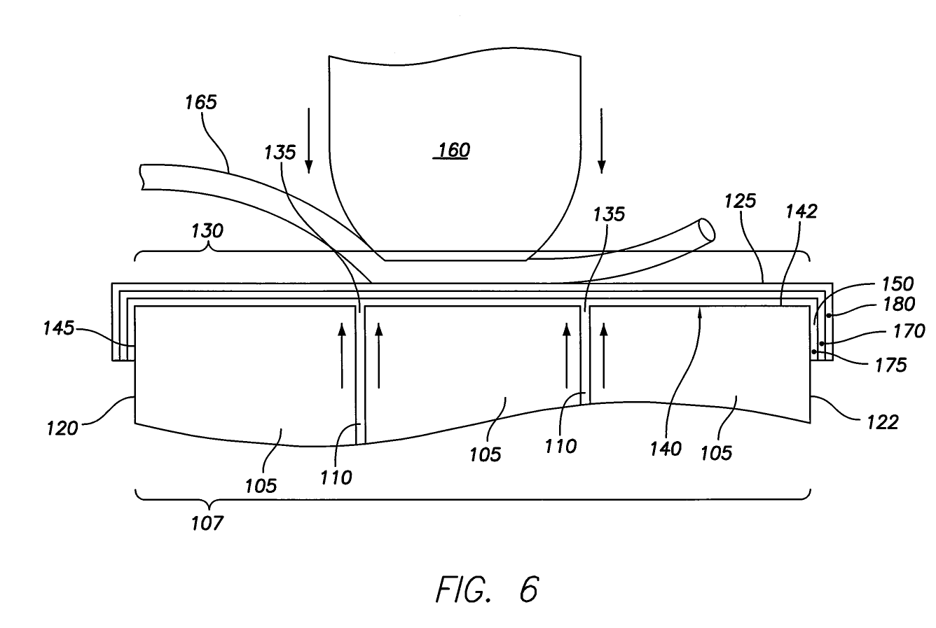

As more clearly depicted in FIG. 5, which is a cross sectional isometric view as taken along section line 5-5 in FIG. 4, each side wire bond pad 125 includes a rib 135 that extends from an inner face 140 of the side wire bond pad 125 into the space between adjacent organic substrate layers 105 (i.e., the space that is occupied by a joining layer 110). Thus, as can be understood from FIG. 6, where the organic PCB substrate 107 is a unitary structure formed of three organic substrate layers 105 joined in a sandwiched manner via the two intervening joining layers 110, two intermediate ribs 135 extend from the inner face 140 of the side wire bond pad 125, each rib occupying an outer peripheral outer extent of the space between adjacent organic substrate layers 105 that would otherwise be occupied by the joining layer 110.

In other embodiments where the organic PCB substrate 107 is a unitary structure formed of only two organic substrate layers or greater than three organic substrate layers, there would be respectively a single intermediate rib 135 or greater than two intermediate ribs 135. For example, if the organic PCB substrate 107 is a unitary structure formed of only two organic substrate layers 105 joined in a sandwiched manner via one intervening joining layer 110, only a single intermediate rib 135 would extend from the inner face 140 of the side wire bond pad 125. As another example, if the organic PCB substrate 107 is a unitary structure formed of four, five or more organic substrate layers 105 joined in a sandwiched manner via the three, four or more intervening joining layer 110, respectively, three, four or more intermediate ribs 135 would extend from the inner face 140 of the side wire bond pad 125.

In some embodiments, additional ribs in the form of a top rib 145 and/or bottom rib 150 may respectively extend along the top surface 120 and/or bottom surface 122 from the inner face 140 of the pad portion 142 of the side wire bond pad 125. In such an arrangement, the additional ribs 145, 150 may respectively form top and bottom wire bond pads 115, 116.

In one embodiment, the intermediate ribs 135 project a distance of between approximately 0.3″ and approximately 0.01″ from the inner face 140 of the side wire bond pad 125 into the space occupied by the joining layer 110. The intermediate ribs 135 may be offset from each other or the top and bottom ribs 145, 150 by a distance of between approximately 0.005″ and 0.05″. The thickness of the intermediate ribs 135 may be between approximately 0.0005″ and approximately 0.004″. The top and bottom ribs 145, 150 may have a projection distance and thickness similar to that of the intermediate ribs 135.

In one embodiment, the ribs 135, 145, 150 may be electrical traces or other configurations formed on the surfaces of the respective locations via such methods as rap around or via hole, and the ribs 135, 145, 150 may be formed of such electrically conductive materials as stainless steel, nickel, copper, gold, platinum or silver.

As can be understood from FIG. 6, which is an enlarged side view of a portion of the cross section side of the side wire bond pad 125 of FIG. 5, the ribs 135, 145, 150 substantially strengthen/reinforce the side or edge 130 of the organic PCB substrate 107. As a result, the side wire bond pad 125 is able to withstand the impact force of the wire bonding tool tip 160 during application of the bonding wire 165 without deflecting or allowing the side or edge 130 of the organic PCB substrate 107 to crack. Also, the ribs 135, 145, 150 substantially increase the resistance of the side or edge 130 and the pad 125 to pulling forces. In some embodiments, the presence of the epoxy joining layers 110, as opposed to simple heat induced joining of the adjacent organic PCB layers 105, substantially increases the ability of the edge 130 to resist failure from impact and pulling forces.

As indicated in FIG. 6, in some embodiments, the side pad 125 has multiple (e.g., three) metal plating layers. For example, an intermediate nickel layer 170 is plated above a bottom copper layer 175 in order to support a top gold layer 180. Applying a nickel layer also helps to strengthen the side pad body. Thus, in some such embodiments, the ribs 135, 145, 150 are formed from the copper layer 175. In some embodiments configured for use in an MRI field, the nickel layer 170 may be eliminated entirely or replaced with another non-magnetic material, such as, for example, copper or nickel.

As can be understood from the preceding discussion, in one embodiment, ribs are added in the spaces between adjacent substrate layers at the periphery of the substrate layers. These ribs are joined to the inner face of the side pad, the ribs acting as beams to help reinforce the side pad against deflection and protect the peripheral edge of the substrate from cracking or other structural failure. As a result, the side pad and the substrate edge below the side pad are sufficiently strong to withstand the impact and pulling forces applied to the side pad during wire bonding.

In one embodiment, for each substrate layer 105 that will be combined into the unitary multi-layer substrate 107, a rib 135 is deposited or otherwise formed as a trace 135 along the peripheral edge of the substrate layer in the location to be occupied by the side pad 125. An epoxy 110 or other joining material is applied between the substrate layers 105. The substrate layers 105, with their respective traces 135, are then sandwiched together and joined via the epoxy 110 such that the peripheral edges of the substrate layers and the traces 135 align, as can be understood from FIG. 5. The inner face or surface 140 of the pad portion 142 of the side pad 125 is joined, e.g., via welding, etc., to the outer edges of the traces 135, the traces 135 thereby becoming the reinforcing ribs 135 of the pad portion 142.

In one embodiment, side pads 125 are preassembled such that the ribs 135 project generally perpendicularly from the inner face 140 of the pad portion 142. An epoxy 110 or other joining material is applied between the substrate layers 105. The substrate layers 105 are then sandwiched together and joined via the epoxy 110 such that the peripheral edges of the substrate layers align. The side pads 125 are mounted on the side edge of the multi-layer substrate 107 such that the ribs 135 are inserted into respective spaces between adjacent substrate layers 105, as shown in FIG. 5.

Although the present invention has been described with reference to preferred embodiments, persons skilled in the art will recognize that changes may be made in form and detail without departing from the spirit and scope of the invention.

What is claimed is:

1. An electronic device having an integrated circuit with a printed circuit board, the electronic device comprising:
multiple layers sandwiched together in a planar unitary structure comprising a top surface, a bottom surface and a structure edge extending between the top surface and the bottom surface, the multiple layers comprising a first organic substrate layer joined to a second organic substrate layer, each organic substrate layer comprising a layer edge and a peripheral surface adjacent the layer edge, each layer edge forming part of the structure edge; and
a wire bond pad comprising an outer face, an inner face generally opposite the outer face, and a first rib, the inner face extending along the structure edge and the first rib projecting generally perpendicular from the inner face between the first organic substrate layer and the second organic substrate layer and extending along the peripheral surface of at least one of the first organic substrate layer or the second organic substrate layer.

2. The electronic device of claim 1, further comprising a wire bond extending from the outer face.

3. The electronic device of claim 1, wherein at least one of the first organic substrate layer or the second organic substrate layer includes a glass reinforced epoxy laminate sheet.

4. The electronic device of claim 3, wherein the glass reinforced epoxy laminate sheet is a N.E.M.A. FR-4 laminate sheet.

5. The electronic device of claim 1, further comprising a joining layer between the first organic substrate layer and the second organic substrate layer, the joining layer join the first organic substrate layer to the second organic substrate layer.

6. The electronic device of claim 5, wherein the joining layer includes an epoxy.

7. The electronic device of claim 1, wherein the first rib includes an electrical trace deposited along the peripheral surface.

8. The electronic device of claim 1, wherein the wire bond pad further comprises a second rib extending generally perpendicular from the inner face along the top surface.

9. The electronic device of claim 1, wherein the wire bond pad further comprises a second rib extending generally perpendicular from the inner face along the bottom surface.

10. The electronic device of claim 1, wherein the wire bond pad further comprises: a second rib extending generally perpendicular from the inner face along the top surface; and a third rib extending generally perpendicular from the inner face along the bottom surface.

11. The electronic device of claim 1, wherein the outer face includes a first electrically conductive metal and the inner face and rib each include a second electrically conductive metal.

12. The electronic device of claim 1, wherein the first electrically conductive metal is gold and the second electrically conductive metal is copper.

13. The electronic device of claim 1, wherein the electronic device includes an implantable medical pulse generator.

14. A method of manufacturing an electronic device, the method comprising:
providing a device housing;
assembling a printed circuit board for an integrated circuit by the method comprising:
a) providing a first organic substrate layer comprising a layer edge and a peripheral surface adjacent the layer edge;
b) providing a second organic substrate layer comprising a layer edge and a peripheral surface adjacent the layer edge;
c) providing a rib that extends along the peripheral surface of at least one of the first organic substrate layer or the second organic substrate layer;
d) joining together into a sandwiched planar unitary structure the first organic substrate layer with the second organic substrate layer, the resulting sandwiched planar unitary structure comprising a top surface, a bottom surface and a structure edge extending between the top surface and the bottom surface, each layer edge forming part of the structure edge;
e) providing a wire bond pad comprising an outer face and an inner face generally opposite the outer face;
f) applying the wire bond pad to the sandwiched planar unitary structure such that the inner face extends along the structure edge; and
g) joining the first rib to the inner face such that the first rib projects generally perpendicular from the inner face, the first rib extending between the first organic substrate layer and the second organic substrate layer; and
placing the printed circuit board in the housing.

15. The method of claim 14, further comprising wire bonding a conductor to the outer face.

16. The method of claim 14, wherein at least one of the first organic substrate layer or the second organic substrate layer includes a glass reinforced epoxy laminate sheet.

17. The method of claim 16, wherein the glass reinforced epoxy laminate sheet is a N.E.M.A. FR-4 laminate sheet.

18. The method of claim 14, further comprising providing a joining layer between the first organic substrate layer and the second organic substrate layer, the joining layer joining the first organic substrate layer to the second organic substrate layer.

19. The method of claim 18, wherein the joining layer includes an epoxy.

20. The method of claim 14, wherein the first rib includes an electrical trace deposited along the peripheral surface.

21. The method of claim 14, further comprising providing a second rib, the second rib extending generally perpendicular from the inner face along the top surface.

22. The method of claim 14, further comprising providing a second rib, the second rib extending generally perpendicular from the inner face along the bottom surface.

23. The method of claim 14, further comprising providing a second rib and a third rib, the second rib extending generally perpendicular from the inner face along the top surface, and the third rib extending generally perpendicular from the inner face along the bottom surface.
